(19) United States
(12) Patent Application Publication
(10) Pub. No.: US 2025/0248030 A1
(43) Pub. Date: Jul. 31, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Shih-Yu Liao, Hsinchu (TW); Chung-Liang Cheng, Changhua (TW)

(73) Assignee: Taiwan Semiconductor Manufacturing Company, Ltd., Hsinchu (TW)

(21) Appl. No.: 18/423,734

(22) Filed: Jan. 26, 2024

(51) Int. Cl. H10B 41/30; G11C 16/04; H10B 41/10; H10B 41/35; H10B 43/10; H10B 43/30; H10B 43/35

(52) U.S. Cl. CPC H10B 41/30; G11C 16/0483; H10B 41/10; H10B 41/35; H10B 43/10; H10B 43/30; H10B 43/35

(57) ABSTRACT

A semiconductor fabrication method includes providing a substrate with a logic device formed on the substrate and a plurality of metal routing layers disposed above the logic device and substrate with metal routing connected to the logic device, the plurality of metal routing layers including an upper metal routing layer with metal lines, vias, and a planarized oxide layer; forming a fin structure over the oxide layer in the upper metal routing layer from IGZO; forming a high-K dielectric layer over the oxide layer and the fin structure; forming a storage gate over channel regions of the fin structure; forming a first control gate on a first side of the storage gate; forming a second control gate on a second side of the storage gate; and connecting the first control gate to a first word line and the second control gate to a second word line.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of an example FinFET transistor that forms a memory cell that can store two bits of data, in accordance with various embodiments.

FIG. 1B is a top view of an example FinFET transistor in a memory device that can store two bits of data, in accordance with various embodiments.

FIG. 1C is a cross-sectional view along cut line A-A′ of FIG. 2B of the example FinFET transistor in a memory device that can store two bits of data, in accordance with various embodiments.

FIG. 2A is a top view of a portion of an example semiconductor device, in accordance with various embodiments.

FIG. 2B is a cross-sectional view of an example transistor of FIG. 2A along an x-axis, in accordance with various embodiments.

FIG. 2C is a cross-sectional view of an example transistor of FIG. 2A along a y-axis, in accordance with various embodiments.

FIG. 2D is a schematic diagram of an example MTP 4×4 NOR array of FIG. 2A, in accordance with various embodiments.

FIGS. 3A and 3B are cross-sectional diagrams of a portion of an example semiconductor device.

FIG. 4A is a top view of a portion of an example semiconductor device, in accordance with various embodiments.

FIG. 4B is a cross-sectional view of an example transistor of FIG. 4A along an x-axis, in accordance with various embodiments.

FIG. 4C is a cross-sectional view of an example transistor of FIG. 4A along a y-axis, in accordance with various embodiments.

FIG. 4D is a schematic diagram of an example MTP NAND array of FIG. 4A, in accordance with various embodiments.

FIGS. 5A and 5B are cross-sectional diagrams of a portion of an example semiconductor device, in accordance with various embodiments.

FIG. 6 is a flow chart depicting an example method for fabricating a semiconductor device, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Multiple-time programmable (MTP) non-volatile memory (NVM) cells can be formed as NAND devices or NOR devices. Embodiments provided herein provide for forming MTP NVM cells during back end of line (BEOL) processing. Embodiments provided herein provide for increasing the device density of NAND and/or NOR devices in an integrated circuit using BEOL processing. In various embodiments, MTP NVM cells are fabricated in upper metallization layers to increase the density of MTP NVM cells in an integrated circuit. In various embodiments, NAND and/or NOR devices are fabricated in upper metallization layers to increase the device density of NAND and/or NOR devices in an integrated circuit. In various embodiments, a single NVM cell is configured to store two bits of data to increase the density of MTP NVM cells in an integrated circuit.

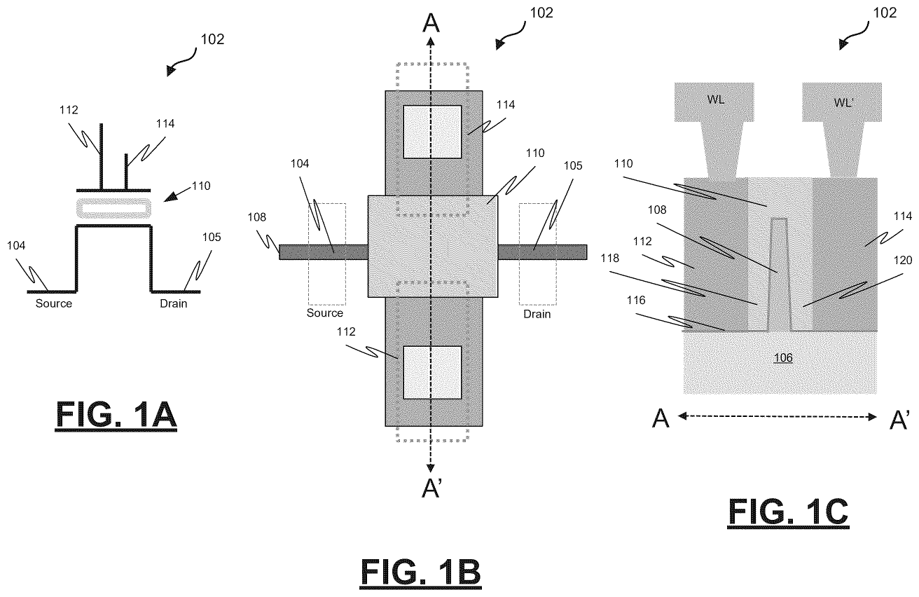

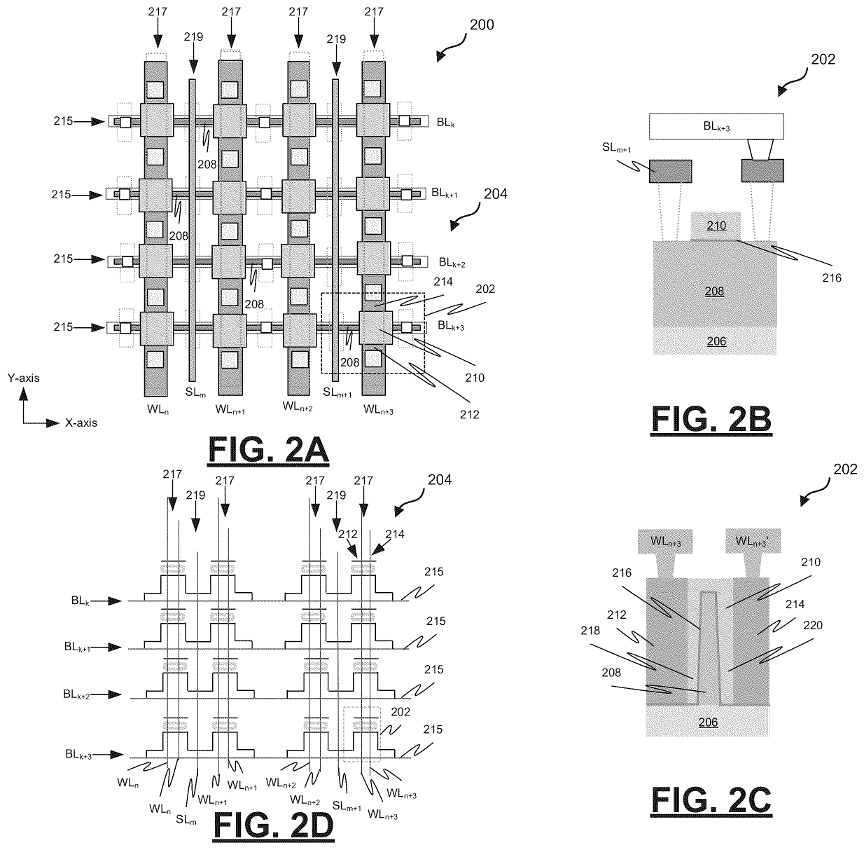

FIG. 1A is a schematic diagram of an example FinFET transistor 102 that forms a memory cell that can store two bits of data, in accordance with various embodiments. FIG. 1B is a top view of the example FinFET transistor 102 in a memory device that can store two bits of data, in accordance with various embodiments. FIG. 1C is a cross-sectional view along cut line A-A′ of FIG. 2B of the example FinFET transistor 102 in a memory device that can store two bits of data, in accordance with various embodiments. The example FinFET transistors 102 include a source and a drain, among other elements. Source/drain region(s) as used herein may refer to a source or a drain, individually or collectively dependent upon the context.

As illustrated in FIGS. 1A-1C, the example FinFET transistor 102 is formed over an oxide layer 106 in a metallization layer above a substrate. The example FinFET transistor 102 includes a fin structure 108 formed over a portion of the oxide layer 106, a storage gate 110 formed over channel regions of the fin structure 108 and a portion of the oxide layer 106 for storing electrons emitted by the fin structure 108, a first control gate 112 formed over the oxide layer 106 and on a first side wall of the storage gate 110, and a second control gate 114 formed over the oxide layer 106 and on a second side wall of the storage gate 110. The example FinFET transistors 102 further includes a high-K dielectric layer 116 disposed between the fin structure 108 and the storage gate 110, between the storage gate 110 and the oxide layer 106, between the first control gate 112 and the oxide layer 106, and between the second control gate 114 and the oxide layer 106. The example FinFET transistors 102 also includes a source terminal 104 and a drain terminal 105 on opposite ends of the fin structure 108.

During write operations, the fin structure 108 can emit electrons for storage in the storage gate 110. The example FinFET transistors 102 are configured to use the first control gate 112 to allow a first bit value (based on the number of electrons stored) to be stored in a first side 118 of the storage gate 110 and configured to use the second control gate 114 to allow a second bit value (based on the number of electrons stored) to be stored in a second side 120 of the storage gate 110.

During read operations, the example FinFET transistors 102 are configured to use the first control gate 112 to allow the first bit value (based on the number of electrons stored) to be read from the a first side 118 of the storage gate 110 and configured to use the second control gate 114 to allow the second bit value (based on the number of electrons stored) to be read from the second side 120 of the storage gate 110. Thus, the example FinFET transistor 102 can be used in a higher density memory cell to store and provide access to two bits of data thereby increasing the density of a memory array versus a memory array that has memory cells that can store and access a single bit of data per memory cell.

FIG. 2A is a top view of a portion of an example semiconductor device 200, in accordance with various embodiments. The example semiconductor device 200 includes a plurality of FinFET transistors 202 arranged as NOR devices in a MTP 4×4 NOR array 204. FIG. 2B is a cross-sectional view of an example transistor 202 of FIG. 2A along an x-axis, and FIG. 2C is a cross-sectional view of an example transistor 202 of FIG. 2A along a y-axis. FIG. 2D is a schematic diagram of the example MTP 4×4 NOR array 204 of FIG. 2A. Note that for clarity, not all features of the semiconductor device 200 are illustrated in FIGS. 2A, 2B, 2C, and 2D, and FIGS. 2A, 2B, 2C, and 2D may illustrate only a portion of the semiconductor structure formed. The example transistors 202 and the example NOR array 204 are fabricated in upper metallization layers, such as between a metal 5 layer and a metal 6 layer or between a metal 6 layer and a metal 7 layer.

As illustrated in FIGS. 2A, 2B, and 2C, the example FinFET transistors 202 are formed on an oxide layer 206 of a metallization layer and include a fin structure 208 formed over a portion of the oxide layer 206, a storage gate 210 formed over channel regions of the fin structure 208 and a portion of the oxide layer 206 for storing electrons emitted by the fin structure 208, a first control gate 212 formed over the oxide layer 206 and on a first side wall of the storage gate 210, and a second control gate 214 formed over the oxide layer 206 and on a second side wall of the storage gate 210. The example FinFET transistors 202 further includes a high-K dielectric layer 216 disposed between the fin structure 208 and the storage gate 210, between the storage gate 210 and the oxide layer 206, between the first control gate 212 and the oxide layer 206, and between the second control gate 214 and the oxide layer 206.

The example FinFET transistors 202 are configured to use the first control gate 212 to allow a first bit value (based on the number of electrons stored) to be stored in a first side 218 of the storage gate 210 and configured to use the second control gate 214 to allow a second bit value (based on the number of electrons stored) to be stored in a second side 220 of the storage gate 210. The example FinFET transistors 202 are also configured to use the first control gate 212 to allow the first bit value (based on the number of electrons stored) to be read from the first side 218 of the storage gate 210 and configured to use the second control gate 214 to allow the second bit value (based on the number of electrons stored) to be read from the second side 220 of the storage gate 210. This arrangement can allow for each FinFET transistor 202 to store and access two bits of data thereby increasing the density of the example NOR array 204.

As illustrated in FIGS. 2A, 2B, 2C, and 2D, in the example NOR array 204, the fin structures 208 of four sets of four series connected FinFET transistors 202 are connected in series in four rows 215. Each row 215 of fin structures 208 is connected at ends of the row to a different bit line (BL) and source/drain connections between neighboring FinFET transistors 202 in a row 215 of fin structures 208 are alternately connected to a different source line 219 or the bit line for the row 215 of fin structures 208. In this disclosure, a source and a drain are interchangeably used, and the structures thereof are substantially the same.

Control gates 212, 214 of the FinFET transistors 202 are connected, in the example NOR array 204, to form four double word line (WL) columns 217. Each double WL column 217 includes two different WLs wherein the first control gates 212 for the FinFET transistors 202 in the column are connected to one of the WLs in the column and the second control gates 214 for the FinFET transistors 202 in the column are connected to the other of the WLs in the column. This arrangement can allow for each FinFET transistor 202 to store and allow access to two bits of data thereby increasing the density of the example NOR array 204.

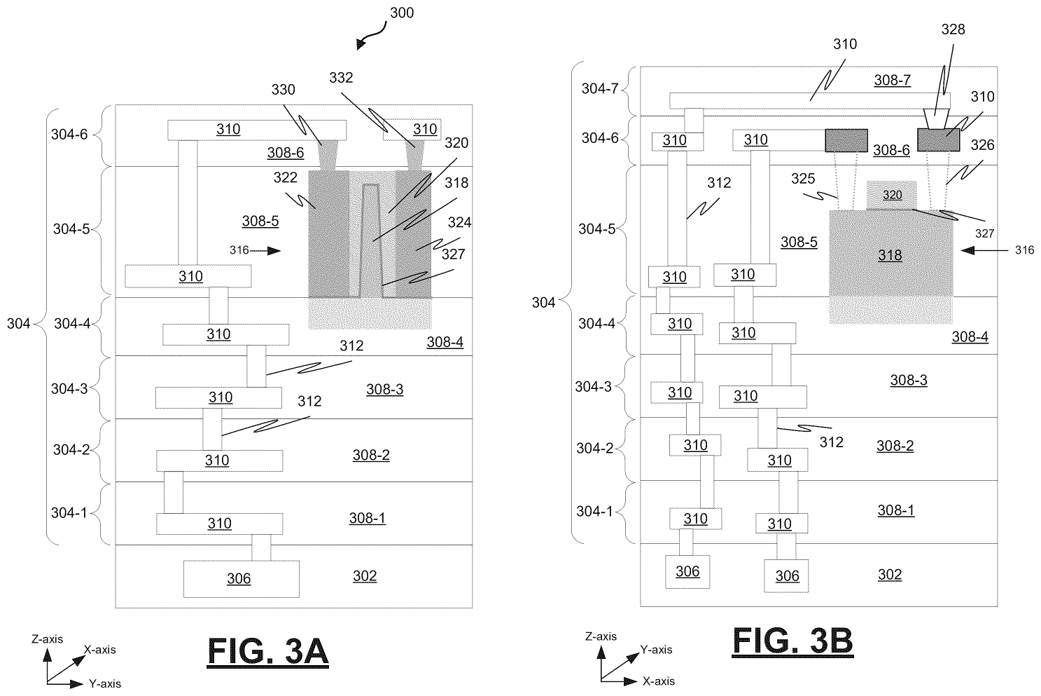

FIGS. 3A and 3B are cross-sectional diagrams of a portion of an example semiconductor device 300. Note that for clarity, not all features of the semiconductor device 300 are illustrated in FIGS. 3A and 3B, and FIGS. 3A and 3B may illustrate only a portion of the semiconductor structure formed. Depicted in FIG. 3A is a cross-sectional view along a y-axis, and FIG. 3B is a cross-sectional view along an x-axis. The example semiconductor device 300 includes a semiconductor substrate 302 and an interconnect structure 304.

The semiconductor substrate 302 may be a semiconductor substrate, such as silicon, doped or undoped, or an active layer of a semiconductor-on-insulator (SOI) substrate. The semiconductor substrate may include semiconductor materials such as Si, Ge, Ga, Zn, In, or O. The semiconductor substrate may include other semiconductor materials such a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The semiconductor substrate 302 can include any number of conductive features and logic device 306 formed in and/or over the semiconductor substrate. Conductive features can include, for example, plugs, interconnects, wiring lines, etc. Logic device 306 can include, for example, transistors, diodes, capacitors, logic devices formed therefrom, etc. For example, the transistors may be metal oxide semiconductor field effect transistors (MOSFETs), complementary metal oxide semiconductor (CMOS) transistors, bipolar junction transistors (BJT), high-voltage transistors, high-frequency transistors, planar FETs such as p-channel field effect transistors (PFETs) or n-channel field effect transistors (NFETs), FinFETs, gate-all-around (GAA) FET devices, or other suitable elements. In various embodiments, a transistor comprises a source, a drain, a gate electrode, a gate dielectric, and a channel. The substrate 302 may further include isolation features (not shown), such as shallow trench isolation (STI) features, deep trench isolation (DTI) features, or local oxidation of silicon (LOCOS) features. The isolation features may define and isolate the various device elements.

The interconnect structure 304 provides routing and electrical connections between logic devices 306 formed in and/or over the substrate 302. The interconnect structure 304 may include a plurality of metallization layers (also referred to herein as metal routing layers)—a first metallization layer 304-1, a second metallization layer 304-2, a third metallization layer 304-3, a fourth metallization layer 304-4, a fifth metallization layer 304-5, a sixth metallization layer 304-6, and a seventh metallization layer 304-7 are shown in the example of FIGS. 3A and 3B.

The example first, second, third, fourth, fifth, sixth, and seventh metallization layers 304-1, 304-2, 304-3, 304-4, 304-5, 304-6, and 304-7, respectively, include a first inter-metal dielectric (IMD) layer 308-1, a second IMD layer 308-2, a third IMD layer 308-3, a fourth IMD layer 308-4, a fifth IMD layer 308-5, a sixth IMD layer 308-6, and a IMD metallization layer 308-7, and may include one or more conductive features, which in this example include metal lines 310 and/or VIAs 312 formed therein in a metallization layer. The conductive features may be electrically connected to active and/or passive devices of the substrate 302 by contacts (not shown in the figures).

In various embodiments, the interconnect structure 304 electrically connects the source, drain, gate electrode, gate dielectric, and/or a channel of a transistor, and other features of the substrate 302 to other features or logic devices 306 on the substrate 302 or within the interconnect structure 304.

In some embodiments, the interconnect structure 304 may be formed using a single and/or a dual damascene process, a VIA-first process, or a metal-first process. In an embodiment, IMD layers (e.g., 308-1, 308-2, 308-3, 308-4, 308-5, 308-6, 308-7) and openings (not shown) may be formed therein using acceptable photolithography, deposition, and etching techniques. The first, second, third, fourth, fifth, sixth, and seventh IMD layers (308-1, 308-2, 308-3, 308-4, 308-5, 308-6, 308-7) may, for example, be or comprise an oxide film, such as silicon oxide, undoped silicon glass (USG), fluorosilicate glass (FSG), boron doped silicate glass (BSG), phosphosilicate glass (PSG), boron phosphorous-doped silicate glass (BPSG), polyethylene oxide (PEOX), thermal oxide, silicon dioxide (SiO₂), or another suitable dielectric material. One or more of the IMD layers (e.g., 308-1, 308-2, 308-3, 308-4, 308-5, 308-6, 308-7) may be made of low dielectric constant (low-k) materials, such as a dielectric constant of less than about 3.0, or less than about 2.5.

Conductive material for the metal lines 310 and/or VIAs 312 may be formed in the openings in the IMD layers from conductive material, such as copper (Cu), aluminum (Al), tungsten (W), nickel (Ni), cobalt (Co), silver (Ag), titanium (Ti), titanium nitride (TiN), gallium (Ga), zinc (Zn), ruthenium (Ru), molybdenum (Mo), indium tin oxide (ITO), combinations thereof, or other applicable materials, and may be formed in the openings using an electro-chemical plating process, chemical vapor deposition (CVD), atomic layer deposition (ALD), physical vapor deposition (PVD), the like, or a combination thereof. After formation of the conductive material, excess conductive material may be removed using, for example, a planarization process such as chemical mechanical polishing (CMP), thereby leaving conductive features in the openings of an IMD layer. The process may then be repeated to form additional IMD layers and conductive features therein. The interconnect structure 304 shown in FIGS. 3A and 3B are merely for illustrative purposes. The interconnect structure 304 may include other configurations and may include one or more metal lines and IMD layers.

An example FinFET transistor 316 is formed on oxide of IMD layer 308-4 of metallization layer 304-4 and includes a fin structure 318 formed over a portion of the IMD layer 308-4, a storage gate 320 formed over channel regions of the fin structure 318 and a portion of the IMD layer 308-4, a first control gate 322 formed over the IMD layer 308-4 and on a first side wall of the storage gate 320, and a second control gate 324 formed over the IMD layer 308-4 and on a second side wall of the storage gate 320. The example FinFET transistors 316 further includes a high-K dielectric layer 327 (e.g., having a dielectric constant greater than about 3.0) disposed between the fin structure 318 and the storage gate 320, between the storage gate 320 and the IMD layer 308-4, between the first control gate 322 and the IMD layer 308-4, and between the second control gate 324 and the IMD layer 308-4.

The example FinFET transistor 316 is formed in a fifth metallization layer 304-5 and forms part of a NOR device that forms a MTP NVM memory cell. In this example, a first source/drain region of the fin structure 318 may be connected to a source line or a source/drain region of another memory cell transistor by a VIA 325 to a metal line 310 in the sixth metallization layer 304-6, a second source/drain region of the fin structure 318 may be connected to a bit line or a source/drain region of another memory cell transistor by a VIA 326 to another metal line 310 in the sixth metallization layer 304-6, which in turn is connected to another metal line 310 in the seventh metallization layer 304-7 by a VIA 328, the first control gate 322 is connected to a first word line by a VIA 330 to a metal line 310 in the sixth metallization layer 304-6, and the second control gate 324 is connected to a second word line by a VIA 332 to a metal line 310 in the sixth metallization layer 304-6. This arrangement can allow for the FinFET transistor 316 to store and allow access to two bits of data.

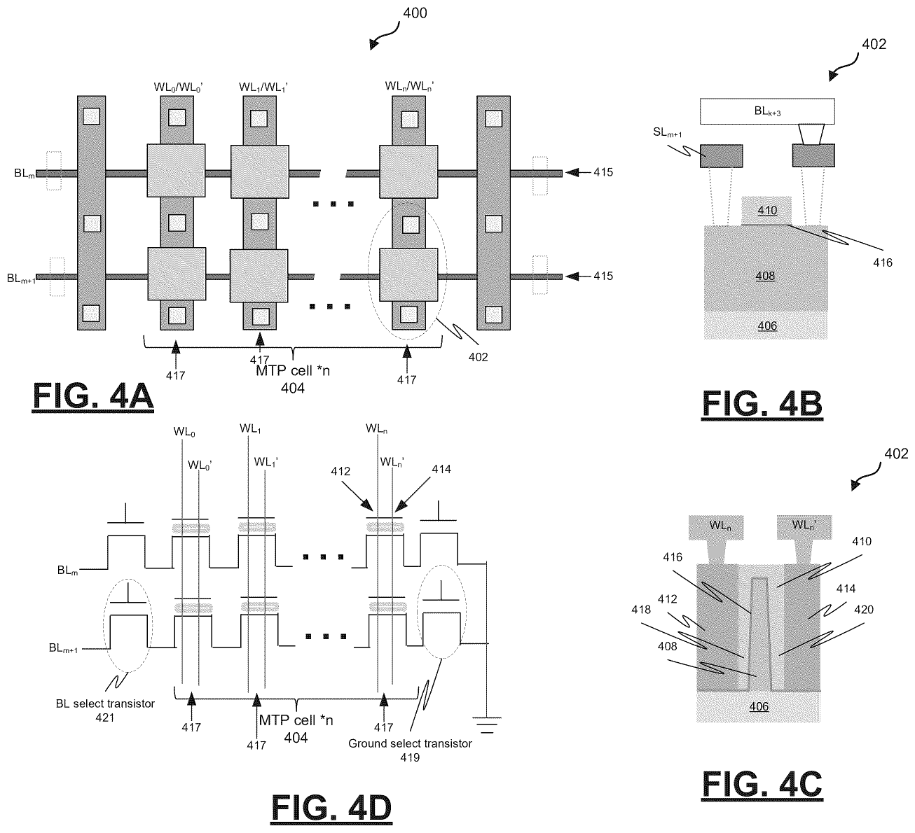

FIG. 4A is a top view of a portion of an example semiconductor device 400, in accordance with various embodiments. The example semiconductor device 400 includes a plurality of FinFET transistors 402 arranged as NAND devices in an MTP NAND array 404. FIG. 4B is a cross-sectional view of an example transistor 402 of FIG. 4A along an x-axis, and FIG. 4C is a cross-sectional view of an example transistor 402 of FIG. 4A along a y-axis. FIG. 4D is a schematic diagram of the example MTP NAND array 404 of FIG. 4A. Note that for clarity, not all features of the semiconductor device 400 are illustrated in FIGS. 4A, 4B, 4C, and 4D, and FIGS. 4A, 4B, 4C, and 4D may illustrate only a portion of the semiconductor structure formed. The example transistors 402 and the example NAND array 404 are fabricated in upper metallization layers, such as between a metal 5 layer and a metal 6 layer or between a metal 6 layer and a metal 7 layer.

As illustrated in FIGS. 4A, 4B, and 4C, the example FinFET transistors 402 are formed on an oxide layer 406 of a metallization layer and include a fin structure 408 formed over a portion of the oxide layer 406, a storage gate 410 formed over channel regions of the fin structure 408 and a portion of the oxide layer 406 for storing electrons emitted by the fin structure 408, a first control gate 412 formed over the oxide layer 406 and on a first side wall of the storage gate 410, and a second control gate 414 formed over the oxide layer 406 and on a second side wall of the storage gate 410. The example FinFET transistors 402 further includes a high-K dielectric layer 416 disposed between the fin structure 408 and the storage gate 410, between the storage gate 410 and the oxide layer 406, between the first control gate 412 and the oxide layer 406, and between the second control gate 414 and the oxide layer 406.

The example FinFET transistors 402 are configured to use the first control gate 412 to allow a first bit value (based on the number of electrons stored) to be stored in a first side 418 of the storage gate 410 and configured to use the second control gate 414 to allow a second bit value (based on the number of electrons stored) to be stored in a second side 420 of the storage gate 410. The example FinFET transistors 402 are also configured to use the first control gate 412 to allow the first bit value (based on the number of electrons stored) to be read from the first side 418 of the storage gate 410 and configured to use the second control gate 414 to allow the second bit value (based on the number of electrons stored) to be read from the second side 420 of the storage gate 410. This arrangement can allow for each FinFET transistor 402 to store and allow access to two bits of data thereby increasing the density of the example NOR array 404.

As illustrated in FIGS. 4A, 4B, 4C, and 4D, in the example NAND array 404, the fin structures 408 of two sets of series-connected FinFET transistors 402 are connected in series in two rows 415. Each row 415 of fin structures 408 is connected at one end of the row to a different bit line (BL) and at another end to a ground select transistor 419, and source/drain connections between neighboring FinFET transistors 402 in a row 415 of fin structures 408 are connected to each other. A bit line select transistor 421 (e.g., formed between metal routing layers or on the substrate) is connected between a bit line and a first of the plurality of MTP NVM memory cells (e.g., FinFET transistor 402) and a ground select transistor 419 (e.g., formed between the metal routing layers or on the substrate) is connected between a ground source and a second of the plurality of MTP NVM memory cells (e.g., FinFET transistor 402).

Control gates 412, 414 of the FinFET transistors 402 are connected, in the example NAND array 404, to form double word line (WL) columns 417. Each double WL column 417 includes two different WLs wherein the first control gates 412 for the FinFET transistors 402 in the column are connected to one of the WLs in the column and the second control gates 414 for the FinFET transistors 402 in the column are connected to the other of the WLs in the column. This arrangement can allow for each FinFET transistor 402 to store and allow access to two bits of data thereby increasing the density of the example NAND array 404.

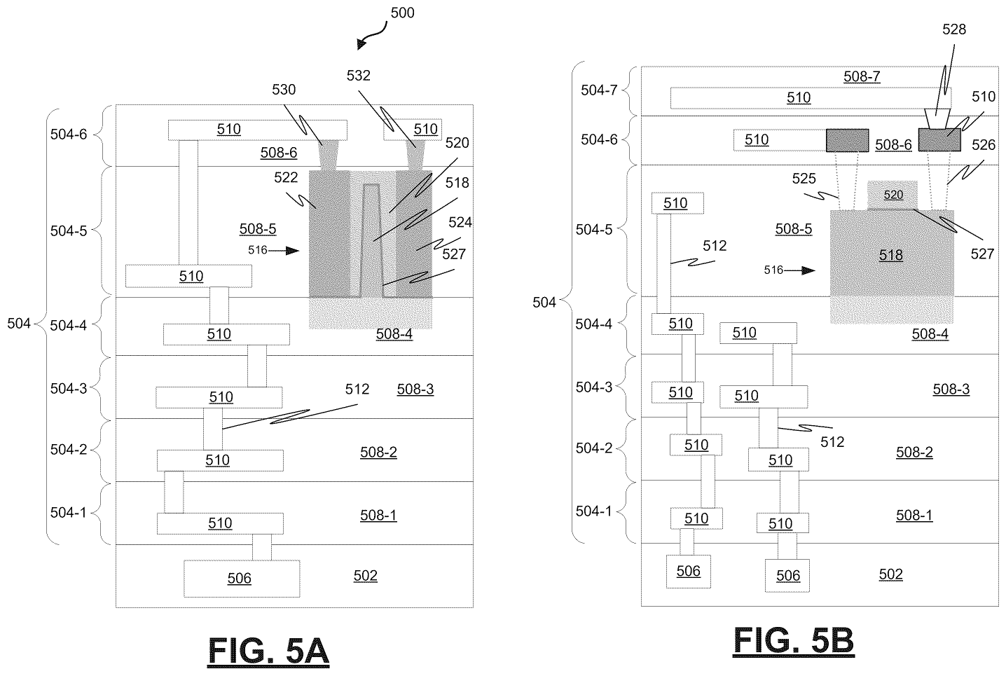

FIGS. 5A and 5B are cross-sectional diagrams of a portion of an example semiconductor device 500. Note that for clarity, not all features of the semiconductor device 500 are illustrated in FIGS. 5A and 5B, and FIGS. 5A and 5B may illustrate only a portion of the semiconductor structure formed. Depicted in FIG. 5A is a cross-sectional view along a y-axis, and FIG. 5B is a cross-sectional view along an x-axis. The example semiconductor device 500 includes a semiconductor substrate 502 and an interconnect structure 504.

The semiconductor substrate 502 may be a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInASP; or combinations thereof. Other substrates, such as multi-layered or gradient substrates, may also be used.

The semiconductor substrate 502 can include any number of conductive features and logic devices 506 formed in and/or over the semiconductor substrate. Conductive features can include, for example, plugs, interconnects, wiring lines, etc. Logic devices 506 can include, for example, transistors, diodes, capacitors, etc. For example, the transistors may be metal oxide semiconductor field effect transistors (MOSFETs), complementary metal oxide semiconductor (CMOS) transistors, bipolar junction transistors (BJT), high-voltage transistors, high-frequency transistors, planar FETs such as p-channel field effect transistors (PFETs) or n-channel field effect transistors (NFETs), FinFETs, gate-all-around (GAA) FET devices, or other suitable elements. In various embodiments, a transistor comprises a source, a drain, a gate electrode, a gate dielectric, and a channel. The substrate 502 may further include isolation features (not shown), such as shallow trench isolation (STI) features, deep trench isolation (DTI) features, or local oxidation of silicon (LOCOS) features. The isolation features may define and isolate the various device elements.

The interconnect structure 504 provides routing and electrical connections between logic devices 506 formed in and/or over the substrate 502. The interconnect structure 504 may include a plurality of metallization layers (also referred to herein as metal routing layers)—a first metallization layer 504-1, a second metallization layer 504-2, a third metallization layer 504-3, a fourth metallization layer 504-4, a fifth metallization layer 504-5, a sixth metallization layer 504-6, and a seventh metallization layer 504-7 are shown in the example of FIGS. 5A and 5B.

The example first, second, third, fourth, fifth, sixth, and seventh metallization layers 504-1, 504-2, 504-3, 504-4, 504-5, 504-6, and 504-7, respectively, include a first inter-metal dielectric (IMD) layer 508-1, a second IMD layer 508-2, a third IMD layer 508-3, a fourth IMD layer 508-4, a fifth IMD layer 508-5, a sixth IMD layer 508-6, and a IMD metallization layer 508-7, and may include one or more conductive features, which in this example include metal lines 510 and/or VIAs 512 formed therein in a metallization layer. The conductive features may be electrically connected to active and/or passive devices of the substrate 502 by contacts (not shown in the figures).

In various embodiments, the interconnect structure 504 electrically connects the source, drain, gate electrode, gate dielectric, and/or a channel of a transistor, and other features of the substrate 502 to other features or logic devices 506 on the substrate 502 or within the interconnect structure 504.

In some embodiments, the interconnect structure 504 may be formed using a single and/or a dual damascene process, a VIA-first process, or a metal-first process. In an embodiment, IMD layers (e.g., 508-1, 508-2, 508-3, 508-4, 508-5, 508-6, 508-7) and openings (not shown) may be formed therein using acceptable photolithography, deposition, and etching techniques. The first, second, third, fourth, fifth, sixth, and seventh IMD layers (508-1, 508-2, 508-3, 508-4, 508-5, 508-6, 508-7) may, for example, be or comprise an oxide film, such as silicon oxide, undoped silicon glass (USG), fluorosilicate glass (FSG), boron doped silicate glass (BSG), phosphosilicate glass (PSG), boron phosphorous-doped silicate glass (BPSG), polyethylene oxide (PEOX), thermal oxide, silicon dioxide (SiO₂), or another suitable dielectric material. One or more of the IMD layers (e.g., 508-1, 508-2, 508-3, 508-4, 508-5, 508-6, 508-7) may be made of low dielectric constant (low-k) materials, such as a dielectric constant of less than about 3.0, or less than about 2.5.

Conductive material for the metal lines 510 and/or VIAs 512 may be formed in the openings in the IMD layers from conductive material, such as copper (Cu), aluminum (Al), tungsten (W), nickel (Ni), cobalt (Co), silver (Ag), titanium (Ti), titanium nitride (TiN), gallium (Ga), zinc (Zn), ruthenium (Ru), molybdenum (Mo), indium tin oxide (ITO), combinations thereof, or other applicable materials, and may be formed in the openings using an electro-chemical plating process, chemical vapor deposition (CVD), atomic layer deposition (ALD), physical vapor deposition (PVD), the like, or a combination thereof. After formation of the conductive material, excess conductive material may be removed using, for example, a planarization process such as chemical mechanical polishing (CMP), thereby leaving conductive features in the openings of an IMD layer. The process may then be repeated to form additional IMD layers and conductive features therein. The interconnect structure 504 shown in FIGS. 5A and 5B are merely for illustrative purposes. The interconnect structure 504 may include other configurations and may include one or more metal lines and IMD layers.

An example FinFET transistor 516 is formed on oxide of IMD layer 508-4 of metallization layer 504-4 and includes a fin structure 518 formed over a portion of the IMD layer 508-4, a storage gate 520 formed over channel regions of the fin structure 518 and a portion of the IMD layer 508-4, a first control gate 522 formed over the IMD layer 508-4 and on a first side wall of the storage gate 520, and a second control gate 524 formed over the IMD layer 508-4 and on a second side wall of the storage gate 520. The example FinFET transistors 516 further includes a high-K dielectric layer 527 (e.g., having a dielectric constant greater than about 3.0) disposed between the fin structure 518 and the storage gate 520, between the storage gate 520 and the IMD layer 508-4, between the first control gate 522 and the IMD layer 508-4, and between the second control gate 524 and the IMD layer 508-4.

The example FinFET transistor 516 is formed in a fifth metallization layer 504-5 and forms part of a NAND device that forms a MTP NVM memory cell. In this example, a first source/drain region of the fin structure 518 may be connected to a source/drain region of a BL select transistor or a source/drain region of another memory cell transistor by a VIA 525 to a metal line 510 in the sixth metallization layer 504-6, a second source/drain region of the fin structure 518 may be connected to a source/drain region of a ground select transistor or a source/drain region of another memory cell transistor by a VIA 526 to another metal line 510 in the sixth metallization layer 504-6, which in turn is connected to another metal line 510 in the seventh metallization layer 504-7 by a VIA 528, the first control gate 522 is connected to a first word line by a VIA 530 to a metal line 510 in the sixth metallization layer 504-6, and the second control gate 524 is connected to a second word line by a VIA 532 to a metal line 510 in the sixth metallization layer 504-6. This arrangement can allow for the FinFET transistor 516 to store and allow access to two bits of data. In various embodiments, at least one of the first control gate 522, the second control gate 524, and the source/drain regions of the fin structure 518 is connected to a logic device 506.

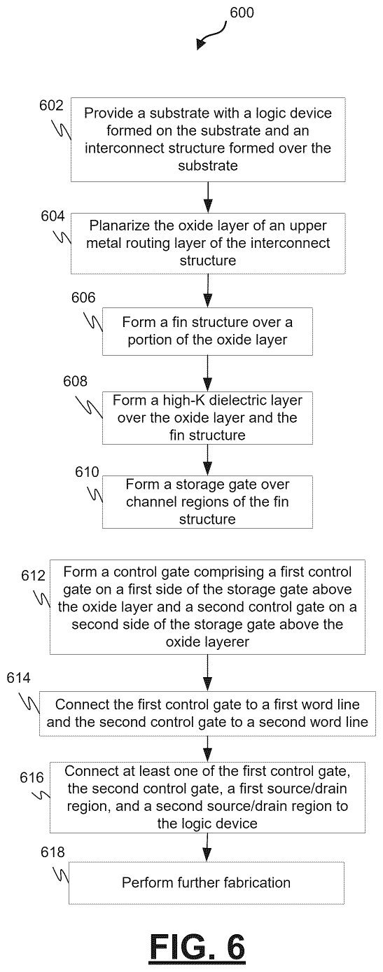

FIG. 6 is a flow chart depicting an example method 600 for fabricating a semiconductor device. FIGS. 2B-2C and FIGS. 3A-3B are cross referenced to provide example embodiments after completion of various blocks of the example method 600.

The example method 600 includes, at block 602, providing a substrate with a logic device formed on the substrate and an interconnect structure formed over the substrate. In various embodiments, the interconnect structure comprises a plurality of metal routing layers disposed above the substrate with metal routing connected to the logic device. In various embodiments, the plurality of metal routing layers include an upper metal routing layer with metal lines, VIAs, and an oxide layer. With reference to FIGS. 2B-2C, and FIGS. 3A-3B, in an example embodiment of block 602, a substrate 302 with a logic device 306 formed on the substrate and an interconnect structure 304 with a plurality of metal routing layers (e.g., metallization layers 304-1, 304-2, 304-3, 304-4, 304-5, 304-6, 304-7) disposed above the substrate is provided. The metal routing layers (e.g., metallization layers 304-1, 304-2, 304-3, 304-4, 304-5, 304-6, 304-7) include metal lines 310 and VIAs 312 connected to the logic device 306. The plurality of metal routing layers (e.g., metallization layers 304-1, 304-2, 304-3, 304-4, 304-5, 304-6, 304-7) include an upper metal routing layer 304-4 with metal lines 310, VIAs 312, and an oxide layer 308-4. In various embodiments, the logic device 306 comprises a transistor device, such as a planar FET, FinFET, or GAA FET device. In various embodiments, the logic device comprises a gate dielectric (e.g., HfO₂, SiO₂, HfO, La, SiON, SiCON, Zn, Zr, etc.), a gate electrode (e.g., Poly-Si, Si, Ti, Ta, Al, W, N, Zn, In, Ga, Ge, C, etc.), a source electrode and a drain electrode (wherein the source/drain comprises Si, Ge, C, P, B, etc.), and a nanosheet channel (e.g., Si). In various embodiments, the substrate comprises Si, Ge, Ga, Zn, In, or O. In various embodiments, the substrate comprises a logic device isolation structure. In various embodiments, the logic device isolation structure in the substrate comprises local oxidation of silicon (LOCOS), shallow trench isolation (STI), deep trench isolation (DTI).

At block 604, the example method 600 includes planarizing the oxide layer of an upper metal routing layer of the interconnect structure. In various embodiments, the planarizing the oxide layer is performed using CMP operations. With reference to FIGS. 2B-2C, and FIGS. 3A-3B, in an example embodiment of block 604, the oxide layer 206/308-4 has been planarized. In some embodiments, the oxide layer may be referred to as an interlayer dielectric (ILD) layer. In some embodiments, the material of the oxide layer includes silicon oxide, silicon nitride, silicon oxynitride, phosphosilicate glass (PSG), borosilicate glass (BSG), boron-doped phosphosilicate glass (BPSG), or low-k materials. The dielectric layer may be formed by any acceptable deposition process, such as spin coating, chemical vapor deposition (CVD), or other suitable methods.

At block 606, the example method 600 includes forming a fin structure over a portion of the oxide layer. In various embodiments, forming a fin structure includes depositing an IGZO layer. Indium gallium zinc oxide (IGZO) is a semiconducting material, consisting of indium (In), gallium (Ga), zinc (Zn) and oxygen (O). By using IGZO, the fin can be formed at a temperature below 300° C. In various embodiments, the IGZO is deposited by ALD or PVD. In various embodiments, after depositing the IGZO, the deposited IGZO is formed in a fin structure. In various embodiments, the fin structure is formed by photolithography, patterning, and etching techniques to cut and etch the IGZO layer into a fin structure. With reference to FIGS. 2B-2C, and FIGS. 3A-3B, in an example embodiment of block 606, a fin structure 208/318 is formed over a portion of the oxide layer 206/308-4.

At block 608, the example method 600 includes forming a high-K dielectric layer over the oxide layer and the fin structure. In various embodiments, the high-K dielectric layer is formed over the oxide layer and the fin structure by a deposition process such as ALD. In some embodiments, the high-K dielectric comprises Hafnium oxide (HfOₓ). In some embodiments, the high-K dielectric comprises Zirconium oxide (ZrOₓ). With reference to FIGS. 2B-2C, and FIGS. 3A-3B, in an example embodiment of block 608, a high-K dielectric layer 216/327 is formed over the oxide layer 206/IMD layer 308-4 and the fin structure 208/318.

At block 610, the example method 600 includes forming a storage gate over channel regions of the fin structure. In various embodiments, the storage gate is a nitride storage gate formed from Silicon nitride (SiN) or Titanium nitride (TiN). In various embodiments, the storage gate is formed by a deposition process, such as CVD or PVD. With reference to FIGS. 2B-2C, and FIGS. 3A-3B, in an example embodiment of block 610, a storage gate 210/320 is formed over channel regions of the fin structure 208/318.

At block 612, the example method 600 includes forming a first control gate on a first side of the storage gate above the oxide layer and a second control gate on a second side of the storage gate above the oxide layer. In various embodiments, forming the first and second control gates comprise depositing a control gate material layer over and around the storage gate using a suitable deposition technique and planarizing the control gate material layer, for example using CMP, to separate the first control gate and the second control gate. In various embodiments, the first and second control gates are formed from a nitride, such as Titanium nitride (TiN) or Tantalum nitride (TaN). With reference to FIGS. 2B-2C, and FIGS. 3A-3B, in an example embodiment of block 612, a first control gate 212/322 is formed on a first side of the storage gate 210/320 above the oxide layer 206/308-4 and a second control gate 214/324 is formed on a second side of the storage gate 210/320 above the oxide layer 206/308-4.

At block 614, the example method 600 includes connecting the first control gate to a first word line and connecting the second control gate to a second word line using VIAs and metal lines. In various embodiments, connecting the first control gate to the first word line and connecting the second control gate to the second word line includes: (i) depositing an IMD oxide layer over the fin structure, first control gate, second control gate, and storage gate; (ii) patterning and etching the IMD oxide layer to cut openings for VIAs and metal lines to connect the first control gate to the first word line and the second control gate to the second word line; and depositing a metal layer for the VIAs and metal lines. In some embodiments, the material of the VIAs and metal lines may include a metal, such as copper, titanium, tungsten, aluminum, or a combination thereof. The VIAs and metal lines may be formed by CVD or plating. With reference to FIG. 3A, in an example embodiment of block 614, the first control gate 322 is connected by a VIA 330 through a metal line 310 to a first word line and the second control gate 324 is connected by a VIA 332 through a metal line 310 to a second word line.

At block 616, the example method 600 includes connecting at least one of the first control gate, the second control gate, a first source/drain region of the fin structure, and a second source/drain region of the fin structure to the logic device. With reference to FIG. 3B, in an example embodiment of block 616, a first source/drain region of fin structure 318 is connected by VIA 325 through metal lines 310 and VIAs 312 to a logic device 306, and a second source/drain region of fin structure 318 is connected by VIA 326 through metal lines 310 and VIAs 312 to a logic device 306. With reference to FIG. 3A, in an example embodiment of block 616, the first control gate 322 is connected by a VIA 330 through metal lines 310 and VIAs 312 to a logic device 306 and the second control gate 324 is connected by a VIA 332 through metal lines 310 and VIAs 312 to the logic device 306.

The method 600 may include, at block 618, further processing steps to complete an integrated circuit. Further processing steps may include forming further interconnections between various elements of the semiconductor device. In various embodiments, the method 600 may include forming connections to form NOR devices. In various embodiments, the method 600 may include forming connections to form NAND devices. In various embodiments, the method 600 may include connecting a first source/drain region of the fin structure to a source line, a second source/drain region of the fin structure to a bit line, and the control gate to a word line. In various embodiments, the method 600 may include connecting: a first source/drain region of the fin structure to a source/drain region of a first series-connected transistor, a second source/drain region of the fin structure to a source/drain region of a second series-connected transistor, and the control gate to a word line.

In some aspects, the techniques described herein relate to a semiconductor device including: a substrate with a logic device formed on the substrate; a plurality of metal routing layers disposed above the substrate with metal routing connected to the logic device; and a plurality of multiple-time programmable (MTP) non-volatile memory (NVM) cells formed between the plurality of metal routing layers, the plurality of memory cells including a FinFET transistor having a fin structure, a storage gate disposed around channel regions of the fin structure for storing electrons emitted by the fin structure, a first control gate formed around a first side wall of the storage gate and connected to a first word line, and a second control gate formed around a second side wall of the storage gate and connected to a second word line.

In some aspects, the techniques described herein relate to a device, wherein the plurality of memory cells include a NOR device.

In some aspects, the techniques described herein relate to a device, wherein a first source/drain region of the fin structure is connected to a source line and a second source/drain region of the fin structure is connected to a bit line.

In some aspects, the techniques described herein relate to a device, wherein the plurality of memory cells include a NAND device.

In some aspects, the techniques described herein relate to a device, wherein a first source/drain region of the fin structure is connected to a source/drain region of a first series-connected transistor and a second source/drain region of the fin structure is connected to a source/drain region of a second series-connected transistor.

In some aspects, the techniques described herein relate to a device, wherein the fin structure is formed from Indium gallium zinc oxide (IGZO).

In some aspects, the techniques described herein relate to a device, wherein the storage gate is formed from Silicon nitride (SiN) or Titanium nitride (TiN) and the control gate is formed from Titanium nitride (TiN) or Tantalum nitride (TaN).

In some aspects, the techniques described herein relate to a device, further including a high-K dielectric layer formed between the storage gate and the fin structure and wherein the high-K dielectric layer includes Hafnium oxide (HfOₓ) or Zirconium oxide (ZrOₓ).

In some aspects, the techniques described herein relate to a semiconductor fabrication method including: providing a substrate with a logic device formed on the substrate and a plurality of metal routing layers disposed above the logic device and substrate with metal routing connected to the logic device, the plurality of metal routing layers including an upper metal routing layer with metal lines, vias, and a planarized oxide layer; forming a fin structure over the oxide layer in the upper metal routing layer from IGZO; forming a high-K dielectric layer over the oxide layer and the fin structure; forming a storage gate over channel regions of the fin structure; forming a first control gate on a first side of the storage gate; forming a second control gate on a second side of the storage gate; connecting the first control gate to a first word line; connecting the second control gate to a second word line; and connecting at least one of the first control gate, the second control gate, and a source/drain region of the fin structure to the logic device using VIAs and metal lines.

In some aspects, the techniques described herein relate to a method, wherein forming the fin structure over the oxide layer in the upper metal routing layer from IGZO includes depositing an IGZO layer by atomic layer deposition (ALD) or physical vapor deposition (PVD) and forming the deposited IGZO layer into a fin structure by patterning and etching techniques.

In some aspects, the techniques described herein relate to a method, wherein forming the high-K dielectric layer over the oxide layer and the fin structure includes depositing the high-K dielectric layer by atomic layer deposition (ALD) and wherein the high-K dielectric layer includes Hafnium oxide (HfOₓ) or Zirconium oxide (ZrOₓ).

In some aspects, the techniques described herein relate to a method, wherein forming the storage gate includes forming a nitride storage gate from Silicon nitride (SiN) or Titanium nitride (TiN) by chemical vapor deposition (CVD) or physical vapor deposition (PVD).

In some aspects, the techniques described herein relate to a method, wherein forming the first control gate and forming the second control gate include depositing a control gate material layer from Titanium nitride (TiN) or Tantalum nitride (TaN) over and around the storage gate and planarizing the control gate material layer using CMP to separate the first control gate from the second control gate.

In some aspects, the techniques described herein relate to a method, further including connecting a first source/drain region of the fin structure to a source line, and a second source/drain region of the fin structure to a bit line.

In some aspects, the techniques described herein relate to a method, further including connecting a first source/drain region of the fin structure to a source/drain region of a first series-connected transistor and a second source/drain region of the fin structure to a source/drain region of a second series-connected transistor.

In some aspects, the techniques described herein relate to a memory device including: a logic device; a plurality of metal routing layers with metal routing connected to the logic device; and a multiple-time programmable (MTP) non-volatile memory (NVM) cell formed in a BEOL (back-end-of-line) process between the plurality of metal routing layers, the memory cell including a FinFET transistor having an IGZO (Indium gallium zinc oxide) fin, a storage gate disposed around channel regions of the IGZO fin, a first control gate formed around a first side wall of the storage gate and connected to a first word line, and a second control gate formed around a second side wall of the storage gate and connected to a second word line.

In some aspects, the techniques described herein relate to a memory device, wherein the memory cell is connected to a plurality of other memory cells to form a NOR device.

In some aspects, the techniques described herein relate to a memory device, wherein the memory cell is connected to a plurality of other memory cells to form a NAND device.

In some aspects, the techniques described herein relate to a memory device, further including a high-K dielectric formed between the storage gate and the IGZO fin.

In some aspects, the techniques described herein relate to a memory device, wherein the logic device includes a planar FET, FinFET, or gate all around (GAA) FET device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate with a logic device formed on the substrate;
a plurality of metal routing layers disposed above the substrate with metal routing connected to the logic device; and
a plurality of multiple-time programmable (MTP) non-volatile memory (NVM) cells formed between the plurality of metal routing layers, the plurality of memory cells comprising a FinFET transistor having a fin structure, a storage gate disposed around channel regions of the fin structure, a first control gate formed around a first side wall of the storage gate and connected to a first word line, and a second control gate formed around a second side wall of the storage gate and connected to a second word line.

2. The device of claim 1, wherein the plurality of memory cells comprise a NOR device.

3. The device of claim 1, wherein a first source/drain region of the fin structure is connected to a source line and a second source/drain region of the fin structure is connected to a bit line.

4. The device of claim 1, wherein the plurality of memory cells comprise a NAND device.

5. The device of claim 1, wherein a first source/drain region of the fin structure is connected to a source/drain region of a first series-connected transistor and a second source/drain region of the fin structure is connected to a source/drain region of a second series-connected transistor.

6. The device of claim 1, wherein the fin structure is formed from Indium gallium zinc oxide (IGZO).

7. The device of claim 1, wherein the storage gate is formed from Silicon nitride (SiN) or Titanium nitride (TiN) and the control gate is formed from Titanium nitride (TiN) or Tantalum nitride (TaN).

8. The device of claim 1, further comprising a high-K dielectric layer formed between the storage gate and the fin structure and wherein the high-K dielectric layer comprises Hafnium oxide (HfOₓ) or Zirconium oxide (ZrOₓ).

9. A semiconductor fabrication method comprising:
providing a substrate with a logic device formed on the substrate and a plurality of metal routing layers disposed above the logic device and substrate with metal routing connected to the logic device, the plurality of metal routing layers including an upper metal routing layer with metal lines, vias, and a planarized oxide layer;
forming a fin structure over the oxide layer in the upper metal routing layer from IGZO;
forming a high-K dielectric layer over the oxide layer and the fin structure;
forming a storage gate over channel regions of the fin structure;
forming a first control gate on a first side of the storage gate;
forming a second control gate on a second side of the storage gate;
connecting the first control gate to a first word line;
connecting the second control gate to a second word line; and
connecting at least one of the first control gate, the second control gate, and a source/drain region of the fin structure to the logic device using VIAs and metal lines.

10. The method of claim 9, wherein forming the fin structure over the oxide layer in the upper metal routing layer from IGZO comprises depositing an IGZO layer by atomic layer deposition (ALD) or physical vapor deposition (PVD) and forming the deposited IGZO layer into a fin structure by patterning and etching techniques.

11. The method of claim 9, wherein forming the high-K dielectric layer over the oxide layer and the fin structure comprises depositing the high-K dielectric layer by atomic layer deposition (ALD) and wherein the high-K dielectric layer comprises Hafnium oxide (HfOₓ) or Zirconium oxide (ZrOₓ).

12. The method of claim 9, wherein forming the storage gate comprises forming a nitride storage gate from Silicon nitride (SiN) or Titanium nitride (TiN) by chemical vapor deposition (CVD) or physical vapor deposition (PVD).

13. The method of claim 9, wherein forming the first control gate and forming the second control gate comprise depositing a control gate material layer from Titanium nitride (TiN) or Tantalum nitride (TaN) over and around the storage gate and planarizing the control gate material layer using CMP to separate the first control gate and the second control gate.

14. The method of claim 9, further comprising connecting a first source/drain region of the fin structure to a source line, and a second source/drain region of the fin structure to a bit line.

15. The method of claim 9, further comprising connecting a first source/drain region of the fin structure to a source/drain region of a first series-connected transistor and a second source/drain region of the fin structure to a source/drain region of a second series-connected transistor.

16. A memory device comprising:
a logic device;
a plurality of metal routing layers with metal routing connected to the logic device; and
a multiple-time programmable (MTP) non-volatile memory (NVM) cell between the plurality of metal routing layers, the memory cell comprising a FinFET transistor having an IGZO (Indium gallium zinc oxide) fin, a storage gate disposed around channel regions of the IGZO fin, a first control gate formed around a first side wall of the storage gate and connected to a first word line, and a second control gate formed around a second side wall of the storage gate and connected to a second word line.

17. The memory device of claim 16, wherein the memory cell is connected to a plurality of other memory cells to form a NOR device.

18. The memory device of claim 16, wherein the memory cell is connected to a plurality of other memory cells to form a NAND device.

19. The memory device of claim 16, further comprising a high-K dielectric formed between the storage gate and the IGZO fin.

20. The memory device of claim 16, wherein the logic device comprises a planar FET, FinFET, or gate all around (GAA) FET device.
